(19) United States
(12) Patent Application Publication
(10) Pub. No.: US 2005/0289423 A1
(43) Pub. Date: Dec. 29, 2005

(54) Built-in self test systems and methods for multiple memories

(75) Inventor: Tadashi Yabuta, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/159,201

(22) Filed: Jun. 23, 2005

(30) Foreign Application Priority Data
Jun. 23, 2004 (JP) P2004-184803

(51) Int. Cl. G11C 29/00; G01R 31/28

(52) U.S. Cl. 714/733

(57) ABSTRACT

A built-in self-test architecture for multiple memories in a chip is proposes in the present invention. In this architecture, a memory testing circuit includes a data generator for generating expected-value data, registers connected in parallel to a plurality of memories respectively so as to be able to transfer, in parallel, memory-readout data from the plurality of memories. The comparators to compare the outputs of registers and the expected-value data with respect to each of the plurality of registers, an identification circuit for identifying the comparator which has detected a disagreement among the plurality of comparators, a readout register which stores the memory-readout data read out from the memory from which the disagreement has been detected and memory-identification information for identifying the memory. The architecture also has an output register which serially reads out the memory-readout data in which the disagreement has been detected and the memory-identification information.

### CROSS-REFERENCES TO RELATED APPLICATIONS

This application is based upon and claims the benefit of priority from the prior Japanese Patent application NO. P2004-184803, filed Jun. 23, 2004, the entire contents of which are incorporated herein by reference.

### BACKGROUND OF THE INVENTION

1. Field of the Invention

The present invention relates to a memory testing circuit and a memory testing method using a built-in self-test technology.

2. Description of the Related Art

A conventional memory testing circuit using a built-in self-test technology has operated as follows. Read-out data of a memory cell to be tested and output data of an expected-value generation circuit are compared in an expected-value comparison circuit. As a pass or fail determination signal, a success signal (e.g., “H”) is outputted if all bits show agreement, and a failure signal (e.g., “L”) is outputted if a disagreement is detected—even in only one bit. Test items held in a test-item detection circuit, address information of a memory cell held in an address register, and bit location information held in a bad-bit detection circuit are stored in a memory for accumulating bad-memory-cell information to minimize the test interruption. After the built-in memory is tested at a speed of the actual specification, the bad-memory-cell information accumulated in the memory for accumulating bad-memory-cell information is read out at a low speed.

In addition, in the conventional memory testing circuit using a built-in self-test technology, the memory to be tested is divided into a plurality of blocks, and memory-readout data and expected-value data of a data generation circuit are compared in a comparator with respect to each block. If a disagreement is detected even in only one bit, the memory-readout data of all blocks are shifted out to an output register.

However, in the conventional memory testing circuit, it is difficult to create a bad-bit map early because the bad-memory-ell information cannot be read out to the outside during the period in which whole address of the memory cells are under test at a speed of the actual specification.

Moreover, because the memories have been tested in a way that the bad-bit map is created by serially outputting the memory-readout data including that of a block where the disagreement of the data has not occurred, the increase in the number of test pattern cycles has caused the increase in the memory capacity of the memory tester and has lengthened the time for testing memories.

### SUMMARY OF THE INVENTION

One or more of the problems outlined above may be solved by the various embodiments of the invention. Broadly speaking the invention comprises systems and methods for improved performance of built-in self-tests (BISTs) in integrated circuits, where variability is introduced into the self test to improve the coverage of the test.

The invention may be implemented in a variety of ways, and a number of exemplary embodiments will be described in detail bellow.

In one exemplary embodiment, a memory testing circuit using a built-in self-test technology which is integrated on a substrate on which a plurality of memories are implemented, and which tests the plurality of memories, includes: (a) a data generation circuit for generating expected-value data; (b) a plurality of registers coupled to the memories, configured to receive, e.g., in parallel, memory-readout data from the memories; (c) a plurality of comparators coupled to the registers, configured to compare outputs of the registers and the expected-value data with respect to the registers; (d) a readout register which is coupled to the registers, which stores the memory-readout data from the memory, the memory read-out data from which the disagreement has been detected among the comparators and memory-identification information from the comparators; and (e) a controller which is coupled to the readout register, and which wads out the memory-readout data in which the disagreement has been detected and the memory-identification information, and outputs (e.g., serially) the memory-readout data and the memory-identification information.

In another exemplary embodiment, a method for testing circuitry including memory comprises: (a) comparing, in parallel, memory-readout data which are transferred in parallel from a plurality of memories to a plurality of registers, and expected-value data with respect to each of the memories; (b) detecting disagreement information when the read-out data and the expected-value data do not agree; (c) outputting memory-identification information for identifying the memory from which disagreement has been detected; (e) storing into a readout register the memory-readout data in which disagreement has been detected and the memory-identification information; (f) and outputting the memory-readout data in which disagreement has been detected and the memory-identification information from the readout register in such a manner that the memory-readout data and the memory-identification information are associated with access information of the memory from which the disagreement has been detected.

Numerous additional exemplary embodiments are also possible.

### BRIEF DESCRIPTION OF THE DRAWINGS

Other objects and advantages of the invention may become apparent upon reading the following detailed description and upon reference to the accompanying drawings.

FIG. 1 is a block diagram of a computer processor according to exemplary embodiments of the present invention;

FIG. 2 is a block diagram of a memory testing block according to one exemplary embodiment of the present invention;

FIG. 3 is a block diagram of a memory testing block according to one exemplary embodiment of the present invention;

FIG. 4 is a flowchart explaining operation of a method according to one exemplary embodiment of the present invention; and

FIGS. 5(a) to 5(g) are data formats used in exemplary embodiments of the present invention.

While the invention is subject to various modifications and alternative forms, specific embodiments thereof are shown by way of example in the drawings and the accompanying detailed description. It should be understood, however, that the drawings and detailed description are not intended to limit the invention to the particular embodiments which are described. This disclosure is instead intended to cover all modifications, equivalents and alternatives falling within the scope of the present invention as defined by the appended claims.

### DESCRIPTION OF THE EMBODIMENT

One or more embodiments of the invention are described below. It should be noted that these and any other embodiments described below are exemplary and are intended to be illustrative of the invention rather than limiting.

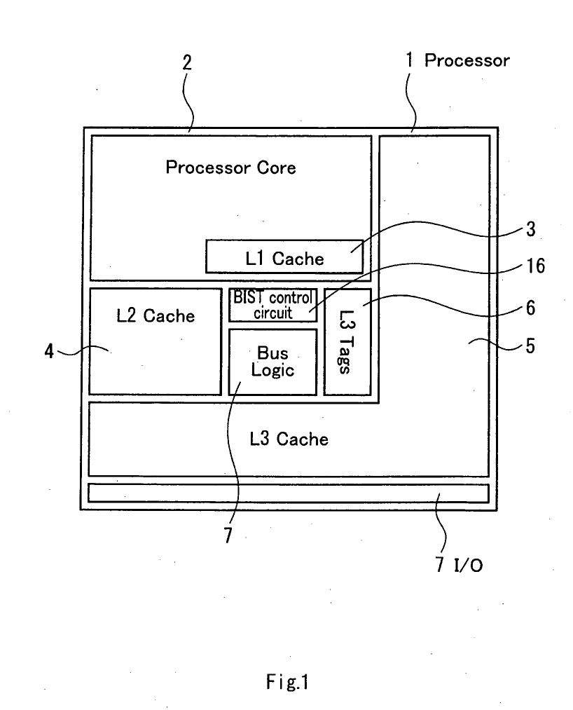

As is shown in FIG. 1, computer processor 1 has many components, for example, such as processor core 2 and a multi-level cache (e.g., including L1 cache 3, L2 cache 4 and L3 cache 5). The multi-level cache may include, for example, SRAM cells or DRAM cells. For example, L2 cache 4 comprises many SRAM blocks. Processor core 2 includes many registers, comprising SRAM cells or CAM. A BIST control circuit 16 is embedded in computer processor 1 for testing memory blocks, such as L1 cache 3, L2 cache 4 and L3 cache 5. The BIST control circuit can execute tests for each memory block in L1 cache 3 in parallel.

### First Embodiment

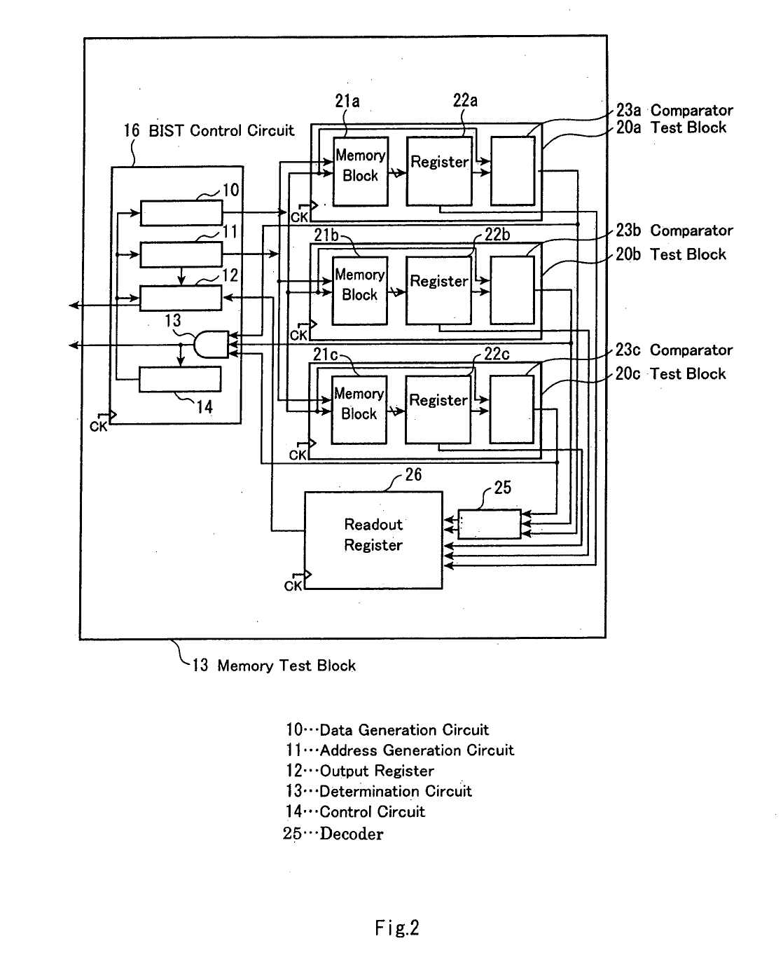

A memory testing system using a built-in self-test (hereinafter abbreviated as “BIST”) technology according to a first exemplary embodiment includes, as shown in FIG. 2, a built-in self-test control circuit 16 (hereinafter abbreviated as “BIST control circuit 16”), test blocks 20a to 20c connected to the BIST control circuit 16, a decoder 25 as an identification circuit connected to the test blocks 20a to 20c, and a readout register 26.

The BIST control circuit 16 includes a data generation circuit 10, an address generation circuit 11, an output register 12, a determination circuit 13, and a disagreement control circuit 14.

The test blocks 20a to 20c include memories 21a to 21c respectively; capture registers 22a to 22c respectively, the capture registers 22a to 22c connected to the memories 21a to 21c respectively, and comparators 23a to 23c respectively, the comparators 23a to 23c connected to the capture registers 22a to 22c respectively. The memories 21a to 21c are connected to the address generation circuit 11 and receive addresses of reading out and writing of data therefrom. Memory test block 13 is one kind of memory block included in System LSL MPU or other kind of processor. In this exemplary embodiment memory block 21a to 21c is buffer of system LSI and comprises SRAM block. Of course, this exemplary embodiment applies to DRAM blocks.

Each of the outputs of the comparators 23a to 23c are connected to a respective input of the decoder 25, and to the determination circuit 13 which is an AND gate.

The determination circuit 13 is connected to the disagreement control circuit 14. When the determination circuit 13 receives a determination signal “L” from at least one of the plurality of comparators 23a to 23c, the determination circuit 13 outputs a signal “L” to the disagreement control circuit 14.

The illustrated memory test block 13 using BIST technology is integrated on a substrate on which the plurality of memories 21a to 21c are also implemented, and tests the plurality of memories 21a to 21c. The memory test block 13 includes the data generation circuit 10 for generating expected-value data; the plurality of capture registers 22a to 22c connected in parallel to the plurality of memories 21a to 21c respectively so as to be able to transfer, in parallel, memory-readout data from the plurality of memories 21a to 21c, the plurality of comparators 23a to 23c connected to the plurality of capture registers 22a to 22c respectively so as to compare the outputs of the plurality of capture registers 22a to 22c and the expected-value data with respect to each of the plurality of capture registers 22a to 22c; the decoder 25, connected to the plurality of comparators 23a to 23c, as an identification circuit for identifying the comparator which has detected a disagreement among the plurality of comparators 23a to 23c; the readout register 26 which is connected to the plurality of capture registers 22a to 22c and the decoder 25 individually, and which stores the memory-readout data read out from the memory from which the disagreement has been detected and memory-identification information for identifying the memory, and the output register 12 which is connected to the readout register 26, and which serially reads out the memory-readout data in which the disagreement has been detected and the memory-identification information, and serially outputs them in such a manner that these are associated with access information of the memory from which the disagreement has been detected.

The BIST control circuit 16 controls the readout register 26, and stores the memory readout data in which the disagreement has been detected and the memory-identification information of the decoder 25. For example, the BIST control circuit 16 stores 256 bit wide memory readout and two-bit memory-identification information. However, the present invention does not limit the data width of the memory-readout data and the bit width of the memory-identification information. The data width and the bit width can be optionally changed in accordance with the circuit design.

When the bit width of the capture register 22a located in the test block 20a is 256-bit wide, for example, the readout register 26 can allow the capture register 22a to transfer a 256-bit wide data in parallel and store it simultaneously. In addition, if the bit widths of the capture register 22b and 22c located in the test blocks 20b and 20c respectively are set to 256-bit wide or less, the readout register 26 can allow the capture registers 22b and 22c to transfer data in parallel and store them simultaneously.

The capacity of the readout register 26 may be optionally determined on the basis of the bit widths of the respective capture registers 22a to 22c and the bit width of the memory-identification information. Considering a case where a plurality of capture registers are found to have bad bits, it is possible to increase the capacity of the readout register 26 in accordance with the number of the test blocks.

The BIST control circuit 16, the test blocks 20a to 20c, and the readout register 26 receive a common clock signal CK and execute a data write cycle, a data read cycle, and a data transfer cycle in synchronization with the clock signal CK.

A description will be given of an operation of the memory testing block shown in FIG. 2. The BIST control circuit 16 causes the data generation circuit 10 to generate expected-value data. This expected-value data has such a data width that the data can be written into the memories 21a to 21c at once.

(a) Data Write Cycle

The BIST control circuit 16 causes the address generation circuit 11 to generate addresses as access information between the start address and the end address of the respective memories 21a to 21c, turns the memories 21a to 21c into a write enabled state, and then writes the expected-value data of the data generation circuit 10 into the memories 21a to 21c.

(b) Data Read Cycle

The BIST control circuit 16 turns the memories 21a to 21c into a read enabled state, and then causes the capture registers 22a to 22c, which are located in the test blocks 20a to 20c respectively, to hold the memory-readout data of the memories 21a to 21c, which are associated with the addresses of the address generation circuit 11.

(c) Memory Data Comparing Cycle

In the test block 20a, the comparator 23a compares the memory-readout data appearing on the output of the capture register 22a and the expected-value data of the data generation circuit 10. If all bits show agreement, a success signal (e.g., “H”) is outputted. If a disagreement is detected even in only one bit, a failure signal (e.g., “L”) is outputted.

In test block 20b, the comparator 23b compares the memory-readout data appearing on the output of the capture register 22b and the expected-value data of the data generation circuit 10 as in block 20a In the test block 20c, the comparator 23c compares the memory-readout data appearing on the output of the capture register 22c and the expected-value data of the data generation circuit 10 as in block 20a also.

The output register 12 holds the addresses of the address generation circuit 11 until the comparison results corresponding to the readout register 26 are decided.

In this way, the memory-readout data read out from the memories 21a to 21c are transferred through the capture registers 22a to 22c respectively, and are subjected to comparison in the comparators 23a to 23c, which are respectively located in the test blocks 20a to 20c, respectively. Thereafter, the comparator of a test block which detects a disagreement even in only one bit outputs a signal “L” as a pass-fail determination signal to the decoder 25 and the determination circuit 13.

A description will be given below by illustrating a case where a bad bit is found in the memory 21a of the first test block 20a before the end address is reached.

When the determination circuit 13 receives a pass-fail determination signal indicating a failure (e.g., “L”) from the comparator 23a which has detected a disagreement, the determination circuit 13 outputs the failure signal to the outside of the memory testing circuit, and also transmits the failure signal to the disagreement control circuit 14. (While the determination circuit is illustrated as an AND circuit in FIG. 2 and is described as being used with an “L” signal representing a failure, one of ordinary skill in the art would understand that the system could instead use an “H” signal to represent a failure and instead use an OR gate.)

(d) Data Transfer Cycle

The disagreement control circuit 14 outputs a test interruption signal to the data generation circuit 10, the address generation circuit 11, and the output register 12, thus halting reading out and writing of data from and to the memories 21a to 21c starting with the next address. Thereafter, the memory-readout data including a bad bit is transferred from the capture register 22a to the readout register 26.

The BIST control circuit 16 causes the capture register 22a to transfer, in parallel, all bits of the memory-readout data subjected to comparison in the comparator 23a to the readout register 26, and writes the data into the readout-register 26. Subsequently, the decoder 25 writes, into the readout register 26, the memory-identification information for identifying the memory 21a from which a disagreement has been detected.

Herein, the “memory-identification information” can be represented by a two-digit binary number “01” outputted from the decoder 25, for example, when a failure signal is output from the first test block while a success signal is output from the second and third test blocks. However, in the present invention, the memory-identification information is not limited to the two-digit binary number, but can be changed to various forms such as a 4-digit octal number and the like in accordance with the circuit design. Alternatively, a bitmap can be used to show the result of each block (e.g., 001 in the example).

(e) Serial Output Cycle

The BIST control circuit 16 controls the output register 12 to cause it to output the address generated in the address generation circuit 11 to the outside of the memory testing block, and subsequently outputs the memory-identification information and the memory-readout data including a bad bit from the readout register 26 to the outside of the memory testing block 17 serially. In this way, it is possible to provide bad-bit map information corresponding to one address.

Subsequently, the BIST control circuit 16 increments or decrements the address of the address generation circuit 11, and then executes the data write cycle, the data read cycle, and the memory data comparing cycle. In this way, the BIST control circuit 16 repeatedly executes each cycle until the end address is reached.

As described above, in the memory test block 13, the address generation circuit 11 is halted every time the disagreement between the memory-readout data and the expected-value data is detected, and all bits of the memory-readout data corresponding to one address and the corresponding memory-identification information are serially outputted to the outside of the memory testing circuit.

Additionally, as a modification of the serial output cycle, a cycle can be employed, in which the memory-readout data in which the disagreement has been detected and the corresponding memory-identification information are accumulated in the readout register 26 without halting the address generation circuit 11, and the memory-readout data and the corresponding memory-identification information accumulated in the readout register 26 are serially read out in such a manner that these are associated with the addresses of the bad bits after the completion of comparing the memory-readout data and the expected-value data performed until the end address is reached, and are serially outputted from the output register 12.

(f) Multi-Block Bad Mode

In the readout register 26, when only one of the memories 21a to 21c provided to the first to third test blocks 20a to 20c respectively has a bad bit with respect to one address, it is sufficient to transfer the data of one capture register in parallel and write the data into the readout register 26 once.

In addition, in the readout register 26, when bad bits exist in a plurality of memories provided to a plurality of test blocks respectively with respect to one address, it is possible to store the information of the bad-bit map only by performing transfers, more than once, of data of the capture registers in which the bad bits exist with priorities assigned to the data, and then writing the data into the readout register 26.

Moreover, when a plurality of comparators detect disagreements concurrently, the BIST control circuit 16 detects a multi-block bad mode, and controls the output register 12.

The output register 12 not only serially reads out data and memory-identification information of one capture register from the readout register 26, but also serially reads out data and memory-identification information of following capture register(s) from the readout register 26. Thereafter, the output register 12 transits the memory-readout data of the bad bits which occur in the plurality of test blocks to a memory tester provided externally to the memory testing circuit

The BIST control circuit 16 causes the plurality of comparators 23a to 23c to sequentially transfer the memory-readout data including bad bits, which are stored in the capture registers 22a to 22c, with priorities assigned thereto (e.g., in the order of the numbers of the first to third test blocks 20a to 20c). Then, the memory-readout data of the capture registers are sequentially written into the readout register 26 in the order of the priorities.

When a bad bit exists in the memory 21a of the first test block 20a, the memory-readout data of the capture register 22a of the first test block 20a is written into the readout register 26 at the first priority. Subsequently, a two-digit binary number “01” for identifying the first test block 20a is written into the readout register 26 as memory-identification information.

When a bad bit exists in the memory 21b of the second test block 20b, the memory-readout data of the capture register 22b of the second test block 20b is written into the readout register 26 at the second priority. Subsequently, a two-digit binary number “10” for identifying the second test block 20b is written into the readout register 26 as memory-identification information.

When a bad bit exists in the memory 21c of the third test block 20c, the memory-readout data of the capture register 22c of the third test block 20c is written into the readout register 26 at the third priority. Subsequently, a two-digit binary number “11” for identifying the third test block 20c is written into the readout register 26 as memory-identification information.

When bad bits exist in the memories 21a and 21b of the first and second test blocks 20a and 20b with respect to one address, the readout register 26 reads out the memory-readout data of the capture register 22b of the second test block 20b subsequently to that of the capture register 22a of the first test block 20a, according to the priority

When bad bits exist in the memories 21b and 21c of the second and third test blocks 20b and 20c with respect to one address, the readout register 26 reads out the memory-readout data of the capture register 22c of the third test block 20c subsequently to that of the capture register 22b of the second test block 20b, according to the priority.

The output register 12 serially reads out the memory-readout data and the memory-identification information from the readout register 26 and transfers them to the outside in a first-in first-out manner at the stage where the memory-readout data assigned with the priority and the corresponding memory-identification information have been written into the readout register 26.

As described above, in the case of the multi-block bad mode, the output register 12 serially transfers the second memory-readout data and the corresponding memory-identification information continuously after serially outputting the first memory-readout data and the corresponding memory-identification information. Accordingly, it becomes possible for the memory tester provided externally to the memory testing circuit to easily identify the multi-block bad mode.

For example, when the memory-readout data corresponding to the first and second test blocks 20a and 20b are recorded in the readout register 26, the output register 12 serially reads out the memory-readout data corresponding to the second test block 20b and the memory-identification information for identifying the second test block 20b continuously after serially reading out the memory-readout data corresponding to the first test block 20a and the memory-identification information for identifying the first test block 20a. The output register 12 then transfers these data to the outside of the memory testing circuit.

In the first embodiment, the output register 12 is capable of storing the memory addresses of a plurality of bad bits instead of only one address, reading out the memory-readout data and the corresponding memory-identification information from the readout register 26, and serially outputting these data in such a manner that these are associated with the addresses of the bad bits.

Since the output register 12 is capable of serially outputting bad bit information including the memory-readout data of the bad bit and the corresponding memory-identification information after the completion of the comparison at the end address of the test, it is possible to perform testing using BIST technology at a speed of the actual specification.

It should be noted that, in order to complete the creation of the bad-bit map early, the bad-bit information may be serially outputted from the output register 12 at a desired time before a test end address of the BIST is reached.

It also should be noted that the output register 12 may serially output the bad-bit information at the stage where a number of pieces of the bad-bit information are accumulated in the readout register 26.

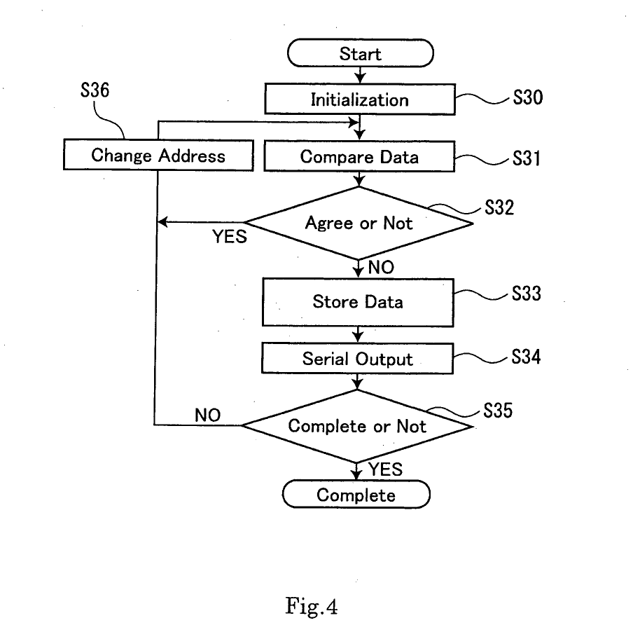

FIG. 4 is a flowchart for explaining an operation of the memory test block of the first embodiment of the present invention. Referring to FIG. 4, a description will be given of the operation sequence of the memory testing circuit.

The BIST control circuit 16 initializes the contents of the data generation circuit 10, the address generation circuit 11, and the output register 12 in an initialization step S30, and performs the built-in self-test process.

The BIST control circuit 16 writes the expected-value data of the data generation circuit 10 into the memories 21a to 21c. The BIST control circuit 16 thereafter turns the memories 21a to 21c into a read enabled state, and causes the capture registers 22a to 22c, which are located in the first to third test blocks 20a to 20c respectively, to hold the memory-readout data of the memories 21a to 21c corresponding to the addresses where the expected-value data have been written.

In a data comparing step S31, the comparators 23a to 23c of the test blocks 20a to 20c compare the memory-readout data appearing on the outputs of the capture registers 22a to 22c with the expected-value data of the data generation circuit 10 respectively.

In an agreement determination step S32, each of the comparators 23a to 23c outputs a success signal if all bits of the memory-readout data agree with those of the expected-value data, and causes the process to branch to an address changing step S36. On the other hand, if a disagreement of the data is detected even in only one bit, the corresponding comparators (23a to 23c) outputs a failure signal, causing the decoder 25 to generate the memory-identification information, and causes the process to proceed to a data storing step S33.

The address changing step S36 increments or decrements the address of the address generation circuit 11 to generate the next address, and then causes the BIST process to proceed to the data comparing step S31.

In the data storing step S33, if the comparator 23a of the first test block 20a detects a disagreement of the data, all bits of the memory-readout data, which is compared with the expected-value data of the data generation circuit 10 and in which the disagreement has been detected, are transferred from the capture register 22a to the readout register 26 in parallel, and are stored in the readout register 26. At the same time, the memory-identification information for identifying the memory 21a provided in the first test block 20a is acquired from the decoder 25, and is stored in the readout register 26.

In a serial output step S34, the output register 12 combines the address acquired from the address generation circuit 11, the memory-readout data read out from the readout register 12, and the memory-identification information. Then the output register 12 serially outputs them to the outside of the memory test block 13.

In the completion step S35, the BIST control circuit 16 determines whether it has completed comparing the memory-readout data and the expected-value data by determining if the test end address is reached. If the entire comparison has not been completed (NO in step S35), the BIST control circuit 16 causes the process to branch to the address changing step S36, and then tests the memories 21a to 21c with respect to the remaining address of the BIST. On the other hand, if the end address of the BIST has been reached (YES in step S35), the BIST control circuit 16 causes the BIST process to end.

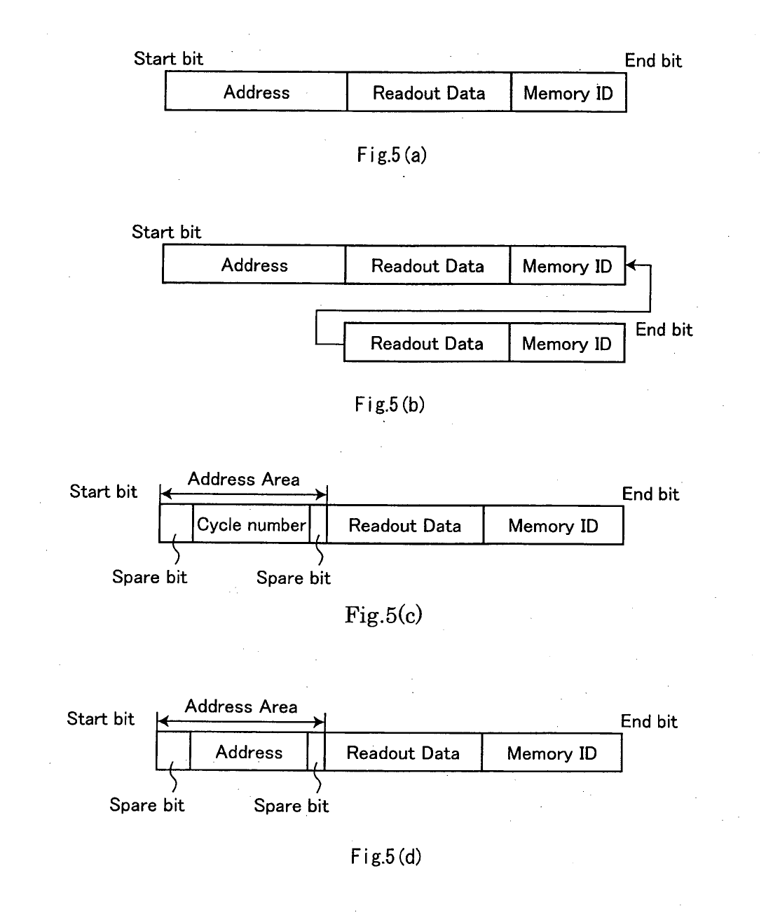

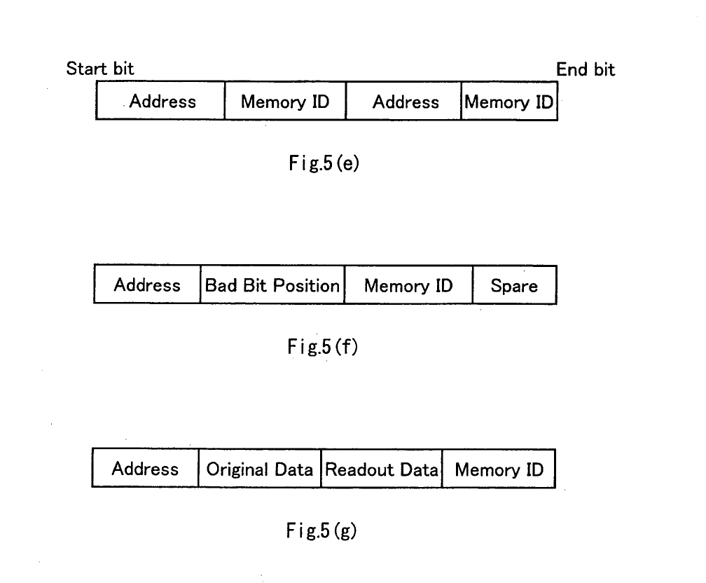

A data format used in the serial output step S34 shown in FIG. 4 is illustrated in FIG. 5(a). In the data format, between the start bit and the end bit, in the first place, the address of the address generation circuit 11 held in the output register 12 (see FIG. 2) is assigned Next to the address, the memory-readout data including a bad bit which is serially read out from the readout register 26 (see FIG. 2) is assigned. Finally, the memory-identification information for identifying the memory which includes a bad bit is assigned.

With the failure analysis of memories using the data format shown in FIG. 5(a), it is possible to easily determine the information of which test blocks the memory-readout data in which a bad bit occurs during the BIST is, on the basis of the memory-identification information, and to determine the location of the memory-readout data in the memory from the address information. Accordingly, it is made possible to complete the creation of the bad-bit map efficiently in a short time.

For example, it is possible to acquire the memory-readout data of the memory 21a of the first test block 20a alone in which a disagreement of the data occurs, and to determine the first test block 20a from the memory-identification information. Thus, this is advantageous in the point that the time for serially outputting the memory-readout data of the memories 21b and 21c provided in the other test blocks 20b and 20c can be eliminated

Another data format used in the serial output step S34 shown in FIG. 4 is illustrated in FIG. 5(b). In the data format, between the start bit and the end bit, the address of the address generation circuit 11 held in the output register 12 (see FIG. 2) is assigned in the first place. After the address (but potentially after a countfield identifying how many blocks are to follow), for example, the memory-readout data of the first test block 20a, the memory-identification information of the memory 21a provided in the first test block 20a, the memory-readout data of the second test block 20b, and the memory-identification information of the memory 21b provided in the second test block 20b, are assigned in this order, each memory-readout data serially read out from the readout register 26 (see FIG. 2) and including a bad bit.

As described above, the data format in which the memory-readout data of the second test block 20b is serially outputted continuously after the memory-identification information for identifying the first test block 20a is adopted. Accordingly, the memory tester provided externally to the memory testing circuit can detect the continuity of the data, and can identify the multi-block bad mode. Alternatively, after each memory identification information there may be at least one bit indicating if additional blocks are to follow. Alternatively, after the address a bitmap representing the various memory IDs may be used to indicate which memories were correct and which had failures. For example, in a system with tree test blocks, after the address may be a field with value 011 to represent that blocks 20b and 20c had failures while block 20a had a successful comparison.

As also described above, even if the memory-readout data and the expected-value data disagree at the same address between the first and second test blocks 20a and 20b, it is possible to acquire the memory-readout data of the memories provided in the respective test blocks and the connected memory-identification information. Accordingly, it is possible to acquire the memory-readout data required earlier than a conventional one.

As further described above, in the first embodiment, since it is not necessary to shift out the memory-readout data of all test blocks serially, the amount of shift of the data is significantly reduced. Accordingly, it is made possible to significantly reduce the test pattern cycle, to reduce the memory capacity of the memory tester provided externally to the memory testing circuit, and to significantly reduce the test time.

The readout register 26 stores the memory-readout data associated with the address in which the bad bit occurs and the corresponding memory-identification information, and can sequentially store the memory-readout data of the bad bit and the corresponding memory-identification information even when memories respectively provided in a plurality of test blocks cause bad bits to occur at the same address.

### Second Embodiment

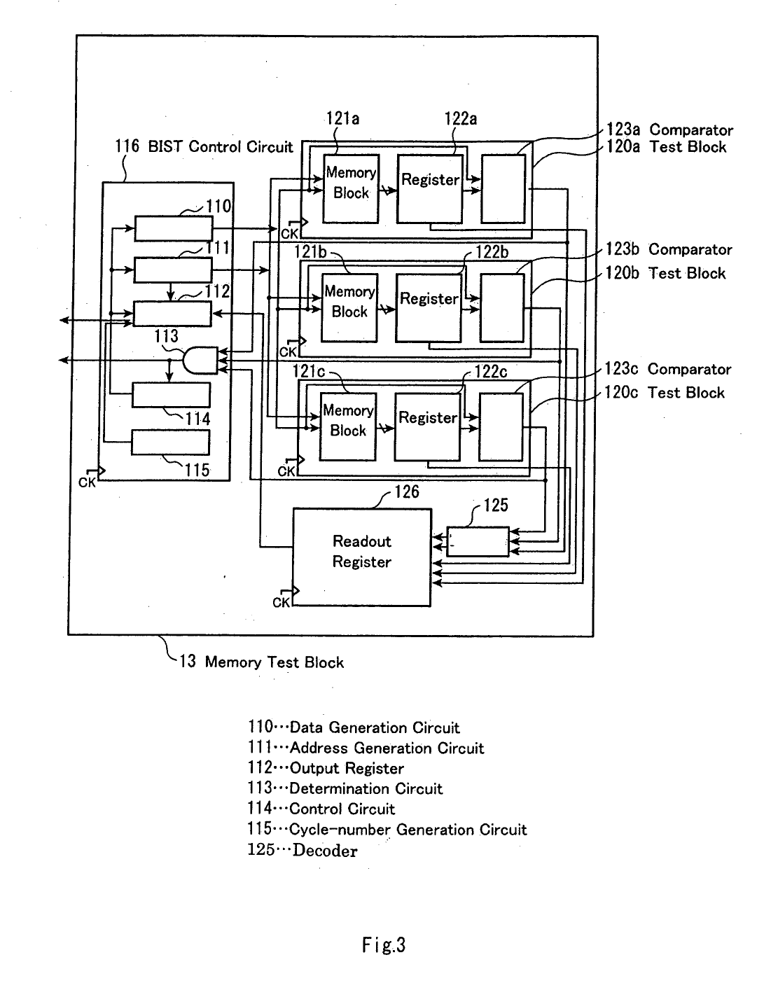

As shown in FIG. 3, a memory testing system using a BIST technology according to a second embodiment of the present invention is integrated on the substrate on which a plurality of memories 121a to 121c are also implemented, and tests the plurality of memories 121a to 121c. The memory testing block 117 includes a data generation circuit 110 for generating expected-value data; a plurality of capture registers 122a to 122c connected to the plurality of memories 121a to 121c respectively so as to be able to transfer, in parallel, memory-readout data from the plurality of memories 121a to 121c; a plurality of comparators 123a to 123c connected to the plurality of capture registers 122a to 122c respectively so as to compare the outputs of the plurality of capture registers 122a to 122c and the expected-value data with respect to each of the plurality of capture registers 122a to 122c; a decoder 125, connected to the plurality of comparators 123a to 123c, as an identification circuit for identifying the comparator which has detected a disagreement among the plurality of comparators 123a to 123c; a readout register 126 which is connected to the plurality of capture registers 122a to 122c and the decoder 125 individually, and which stores the memory-readout data read out from the memory from which the disagreement has been detected and memory-identification information for identifying the memory, a cycle-number generation circuit 115 for generating a cycle number of a test in which number cycle a disagreement of data has been detected; and an output register 112 which is connected to the readout register 126 and the cycle-number generation circuit 115, and which serially reads out the memory-readout data in which the disagreement has been detected and the memory-identification information, and serially outputs them in such a manner that these are associated with the cycle number of the test in which number cycle the disagreement of the data has been detected.

Incidentally, as for the same elements as those of the first embodiment, redundant descriptions will be omitted.

The second exemplary embodiment is different from the first exemplary embodiment in that the cycle-number generation circuit 115 generates a cycle number of a test instead of the address generated by the address generation circuit 111, the cycle number is outputted to the outside of the memory testing circuit, and thereby a bad-bit map is created.

The cycle-number generation circuit 115 counts the periods of the clock signal CK after the initialization of the BIST, and outputs the cycle number of the test which is counted until a test interruption signal of the disagreement control circuit 114 is outputted.

However, the present invention is not limited to the configuration in which the periods of the clock signal CK are counted. For example, by counting a number of times that the addresses have been generated in the address generation circuit 111, it is made possible to detect what number data read out from the memories 121a to 121c the memory-readout data is, and to determine in which test cycle the memories 121a to 121c causes a bad bit to occur.

The output register 112 can cause the bad-bit map to be created in the outside of the memory testing circuit by serially and sequentially outputting the cycle number generated by the cycle-number generation circuit 115, the memory-readout data acquired from the readout register 126, and the memory-identification information.

Additionally, since the bad-bit map is created on the basis of the cycle number of the test, it is possible to save the trouble to calculate what number data the memory-readout data is, on the basis of the address information of the memories 121a to 121c. Accordingly, it is possible to provide the failure analysis information efficiently.

A data format outputted from the output register 112 shown in FIG. 3 is illustrated in FIG. 5(c). In the data format, between the start bit and the end bit, in the first place, spare bits, the cycle number acquired from the cycle-number generation circuit 15, and spare bits are assigned in this order within a bit width of the longest address.

Next to the end bit of the longest address, the memory-readout data acquired from the readout register 126 is assigned. Finally, the memory-identification information is assigned.

Herein, the bit width of the “longest address” can be set to the same bit width as that of the output register 112. The bit width that can address all bits of the memory having the largest capacity among the plurality of memories 121a to 121c is fixed in the data format as the longest address.

In addition, as for the “spare bits”, a dummy data, in which all bits are “1” or “0” and which can be identified in the memory tester, can be assigned.

Since the cycle-generation circuit 115 generates the cycle number which has a bit width smaller than the bit width of the longest address, the spare bits are placed before and after the cycle number to match the bit width of the cycle number with the bit width of the longest address in the data format.

In addition, since the memory-readout data and the corresponding memory-identification information are assigned continuously after the longest address with the fixed length, it is possible to easily create the bad-bit map by the use of the memory tester provided externally to the memory testing circuit.

As shown in FIG. 5(d), it is possible to assign, into the bit width of the longest address, an address of a memory with a middle capacity to a small capacity, before and after which the spare bits are assigned, and it is possible to store the data into the output register 112. Thus, this is advantageous in the point that it is not necessary to provide different output registers corresponding to addresses with different bit widths.

In addition, since the memory-readout data and the corresponding memory-identification information are assigned continuously after the longest address with the fixed length, it is possible to easily create the bad-bit map by the use of the memory tester provided externally to the memory testing circuit.

The data formats shown in FIGS. 5(a) to 5(d), which are described in the first and second embodiment, are merely examples. The order of the placement of the data can be changed as shown in FIGS. 5(e) to 5(g) as appropriate by those skilled in the art in accordance with the circuit design. For example, FIG. 5(e) is modification of FIG. 5 (a) and FIG. 5 (b), which is deleting Readout Data for each memory block from data format. That makes data format simple. FIG. 5 (f) has Bad Bit Position information instead of Readout Data That makes finding bad bit for memory block easier. FIG. 5 (g) has Original Data for memory block and Readout Data for the memory block, instead of Readout Data. That makes finding bad bit for each memory block easier.

Moreover, other fields, such as a count of the number of blocks of bad readout data per address may be included. Alternatively, other fields such as a header may provide information about the data to be read out. For example, the header may describe which format of multiple formats (e.g., the formats of FIGS. 5(a) to 5(g)) is to be used in a next block so that plural formats can be used in the same stream of information.

It should be noted that the operation and effects described in the embodiments of the present invention are merely ones which are the most advantageous operation and effects obtained from the present invention. The operation and effects of the present invention are not limited to those described in the embodiments of the present invention.

1. A built-in self-test chip architecture for multiple memories, at least one of the memories having different sized address width and word size defined by bits, the chip comprising:
a data generator for generating expected-value data;
a plurality of registers coupled to the memories, configured to receive, in parallel, memory-readout data from the memories;
a plurality of comparators coupled to the registers, configured to compare outputs of the registers and the expected-value data with respect to the registers, and to send out a signal including a comparison result;
a readout register which is coupled to the registers, which stores the memory-readout data from the memory, the memory-readout data from which disagreement has been detected among the comparators, and memory-identification information from the comparator, and
a controller which is coupled to the readout register, and which reads out the memory-readout data in which the disagreement has been detected and the memory-identification information, and serially outputs the memory-readout data and the memory-identification information.

2. The built-in self-test single chip architecture according to claim 1, wherein the controller reads out the memory-readout data serially.

3. The built-in self-test single chip architecture according to claim 1, further comprising decoder, configured to receive the signal from the comparator and change to the memory-identification information.

4. The built-in self-test single chip architecture according to claim 1, wherein the memories are SRAM.

5. The built-in self-test single chip architecture according to claim 1, wherein the controller comprises an output register, the output register having coupled to read-out register, and configured to output the memory-readout data and the memory-identification information.

6. The built-in self-test single chip architecture according to claim 1, further comprising an identification circuit, coupled to each of the comparators, for identifying the comparator of the plurality of comparators which has detected a disagreement.

7. The built-in self-test single chip architecture according to claim 1, wherein the controller further comprises a cycle-number generator for generating a cycle number of a test, and the cycle-number generator outputs the cycle number in which number cycle the disagreement of the data is detected.

8. The built-in self-test single chip architecture according to claim 1, wherein the controller further comprises a interrupt controlling circuit which, when the interrupt controlling circuit receives fail signal from the comparator, sends interrupt signal to the data generator.

9. The built-in self-test single chip according to claim 1, wherein the read-out register receives a memory identification information which identify detected memory when the interrupt control circuit receives fail signal from the comparator.

10. The built-in self-test single chip according to claim 1, wherein the memories are DRAM.

11. A method for testing circuitry including memory comprising:
comparing, in parallel, memory-readout data which are transferred in parallel from a plurality of memories to a plurality of registers, and expected-value data with respect to each of the memories;
detecting disagreement information when the read-out data and the expected-value data does not agree;
outputting memory-identification information for identifying the memory from which disagreement has been detected;
storing the memory-readout data in which disagreement has been detected and the memory-identification information into a readout register; and
outputting the memory-readout data in which disagreement has been detected and the memory-identification information from the readout register in such a manner that the memory-readout data and the memory-identification information are associated with access information of the memory from which the disagreement has been detected.

12. The method according to claim 11, wherein the memory read-out data comprises address information at which the disagreement has been detected.

13. The method according to claim 11, wherein the memory-identification information comprises an identifier identifying a memory block at which the disagreement has been detected.

14. The method according to claim 11, wherein the memory-readout data further comprises a number of a cycle in which the disagreement of the data is detected.

15. The memory testing method according to claim 11, further comprising,
after detecting disagreement, sending signal including disagreement information;
receiving disagreement information; and
sending interrupt signal to stop sending data to the memories.

16. The memory testing method according to claim 11, further comprising:
serially outputting the memory-readout data and memory identification information out of a semiconductor chip having built-in self test architecture.

17. The memory testing method according to claim 11, wherein the memory-readout data and memory identification information only relate to a memory block in which disagreement was detected.

18. The memory testing method according to claim 11, wherein outputting comprises outputting the memory-readout data in which the disagreement has been detected out of a semiconductor chip having the built-in self test architecture.

19. The memory testing method according to claim 11, wherein the method is implemented in built-in self-test circuitry.

20. The memory testing method according to claim 11, the memory is DRAM.

21. A system for testing a circuit including memory:
a controller coupled to memory blocks, each memory block having a register,
a checking circuit coupled to the each memory block and the controller, the checking circuit identifying disagreement data between readout data from the memory block and expecting data; and
an outputting circuit outputting disagreement data corresponding to a result of the checking circuit.

22. The system according to claim 20, wherein the checking circuit send signal to interrupt sending expecting data to memory blocks when the checking circuit receives disagreement data from the memory block.

23. The system according to claim 20, the memory read-out data including read out data from the memory block and memory identity information which identifies the memory block.

24. The system according to claim 20, further comprising a computer readout data format, including information regarding memory address, readout data from the memory block and identification for the memory block.

25. A computer processor comprising;
an on-chip memory, and
a built self test circuit for testing the on-chip memory, the built-in self test circuit comprising:
a data generator for generating expected-value data;
a plurality of registers coupled to the memories, configured to receive, in parallel, memory-readout data from the memories;
a plurality of comparators coupled to the registers, configured to compare outputs of the registers and the expected-value data with respect to the registers, and to send out a signal including a comparison result;
a readout register which is coupled to the registers, which stores the memory-readout data from the memory, the memory-readout data from which disagreement has been detected among the comparators, and memory-identification information from the comparator, and
a controller which is coupled to the readout register, and which reads out the memory-readout data in which the disagreement has been detected and the memory-identification information, and serially outputs the memory-readout data and the memory-identification information.

26. The computer processor as claimed in 25, wherein the on-chip memory comprises a level 1 cache.

27. The computer processor as claimed in 25, wherein the on-chip memory comprises DRAM memory block.
